(19) United States
(12) Patent Application Publication
(10) Pub. No.: US 2008/0057614 A1
(43) Pub. Date: Mar. 6, 2008

(54) COLOR IMAGE SENSOR DEVICE AND FABRICATION METHOD THEREOF

(76) Inventors: Tsai Shian-Ching, Fengshan City (TW); Chung Sian-Min, Xindian City (TW); Chia-Chiang Wang, Wuri Shiang (TW); Yu-Wan Chen, Hsinchu City (TW); Chen Shih Lan, Yilan City (TW); Fu Zhe Lee, Yujing Shiang (TW)

Correspondence Address: BIRCH STEWART KOLASCH & BIRCH, PO BOX 747, FALLS CHURCH, VA, 22040-0747, US

(21) Appl. No.: 11/934,002

(22) Filed: Nov. 1, 2007

Related U.S. Application Data
(62) Division of application No. 11/000,935, filed on Dec. 2, 2004.

(30) Foreign Application Priority Data
Jun. 8, 2004 (TW) 93116405

(51) Int. Cl. H01L 21/00

(52) U.S. Cl. 438/70; 257/E31.001

(57) ABSTRACT

A color image sensor device and fabrication method thereof. A passivation layer and a first planarization layer are sequentially formed on a substrate. A plurality of color filter elements are disposed over the first planarization layer corresponding to the sensor pixel array. A second planarization layer and a third planarization layer are sequentially formed over the first planarization layer. The third planarization layer has an opening formed corresponding to a contact pad. A third opening in the first planarization layer and the passivation layer corresponds to the contact pad.

### CROSS-REFERENCE TO RELATED APPLICATIONS

This application is a Divisional of co-pending application Ser. No. 11/000,935, filed on Dec. 2, 2004, and for which priority is claimed under 35 U.S.C. §120; and this application claims priority of Application No. 093116405, filed in Taiwan, R.O.C. on Jun. 8, 2004 under 35 U.S.C. §119; the entire contents of all are hereby incorporated by reference.

### BACKGROUND OF THE INVENTION

1. Field of the Invention

The present invention relates to a method of fabricating a color image sensor device, and in particular to a method of fabricating a color image sensor device with protected contact pads and uniform color filter layers.

2. Brief Discussion of the Related Art

Color image sensor chips usually comprise a sensor pixel array disposed in a central region and a plurality of contact pads in a peripheral region. In conventional fabrication, the sensor pixel array and the contact pads are preformed in fabs by front-end process with a color filter layer then fabricated thereon.

FIG. 1 is a top view of a conventional color image sensor device chip 1, having a sensor pixel array 12 in a central region and a plurality of contact pads 13 in a periphery region. A passivation layer is formed on the sensor pixel array 12 prior to the front-end process forming the same ends. Contact pads 13 and openings thereof are formed corresponding to the contact pads 13, functioning as connection points or test points. Formation of the described openings, however, results in a drop height, generating a various-color filter layer in sequential processes. Thus, strip defects 15, referred to yellow strips, are thus formed. Moreover, the alkaline developer solution used for forming color filter layers of red, green and blue colors can oxidize or corrode the exposed contact pads.

In U.S. Pat. No. 6,344,369, Huang et al. provide a method of fabricating a color image sensor device capable of preventing contact pads from developer solution damage, in which FIGS. 2A-2E show cross sections along line V-V′ of FIG. 1, illustrating fabrication of a conventional color image sensor device chip.

In FIG. 2A, a semiconductor substrate 10 with a sensor pixel array (not shown) and contact pads 13 thereon is provided. A passivation layer 20 is formed on the semiconductor substrate 10 to cover the sensor pixel array and the contact pads 13.

In FIG. 2B, a first planarization layer 30 is formed on the passivation layer 20. The first planarization layer 30 may comprise photoresist and has a plan surface after planarization is performed thereon.

In FIG. 2C, individual color filter layers 40R, 40G, 40B of red, green and blue colors are then formed on the first planarization layer corresponding to the sensor pixel array. The color filter layers 40R, 40G and 40B are formed by repeated spin-coating, exposure and development.

In FIG. 2D, a second planarization layer 50 is formed on the first planarization layer 30, covering the color filter layers 40R, 40G, 40B. Next, sequential exposure and development steps are performed, forming a first opening 60a in the first and second planarization layer 30, 50 and exposing the top surface of the passivation layer 20.

In FIG. 2E, dry etching using the first and second planarization layers 30, 50 as etching masks forms a second opening 60b in the passivation layer 20 and exposes the top surface of the contact pad 13.

The method disclosed in U.S. Pat. No. 6,344,369 prevents the contact pads 13 from oxidation or corrosion during color image sensor device fabrication. During the disclosed fabrication, however, the first planarization layer 30 is photolithographically exposed, developed and baked several times. Thus, the first opening 60a cannot be formed in the first and second planarization layers 30, 50 by a sequential development step, making the fabrication step in FIG. 2D unworkable.

### SUMMARY OF THE INVENTION

Accordingly, an embodiment of the invention provides a method for forming a color image sensor device, comprising providing a substrate having a sensor pixel array and a contact pad. A passivation layer is formed on the substrate, covering the sensor pixel array and the contact pad. A first planarization layer is formed on the passivation layer. A plurality of color filter elements are formed on the first planarization layer in positions corresponding to the sensor pixel array. A second planarization layer is formed on the first planarization layer, covering the color filter elements. A first opening is formed in the second planarization layer, exposing the first planarization layer, wherein the first opening is formed in a position corresponding to the contact pad. Dry etching performed on the first planarization layer along the first opening forms a second opening in the first planarization layer and the passivation layer and exposes the contact pad.

A color image sensor device is also provided, comprising a substrate having a sensor pixel array and a contact pad thereon and a passivation layer disposed over the substrate, covering the sensor pixel array and the contact pad. A first planarization layer covers the passivation layer and a plurality of color filter elements over the first planarization layer corresponding to the sensor pixel array. A second planarization layer over the first planarization covers the color filter elements and a third planarization layer over the second planarization comprises an opening corresponding to the contact pad. A second opening is formed in the second planarization layer corresponds to the contact pad, also does a third opening in the first planarization layer and the passivation layer.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the subsequent detailed description and the accompanying drawings, which are given by way of illustration only, and thus are not limitative of the present invention, and wherein:

FIG. 1 is a top view of a conventional color image sensor device chip 1, having a sensor pixel array in a central region and a plurality of contact pads in a periphery region.

FIGS. 2A-2E are cross sections along the V-V′ line of FIG. 1, illustrating fabrication steps according to a conventional method of forming a color image sensor chip;

FIGS. 3A-3F are cross sections of a method for forming a color image sensor chip according to an embodiment of the invention, illustrating fabrication steps thereof.

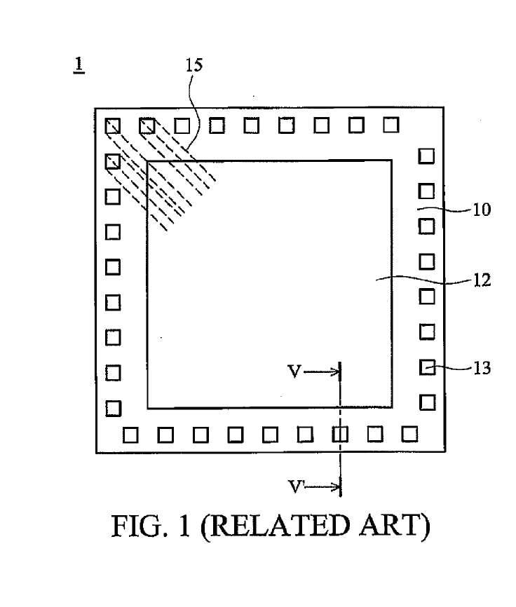

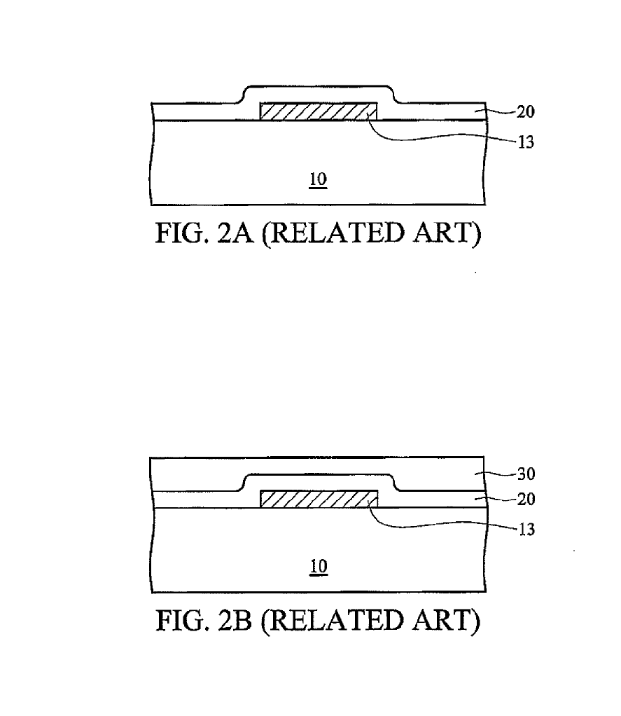

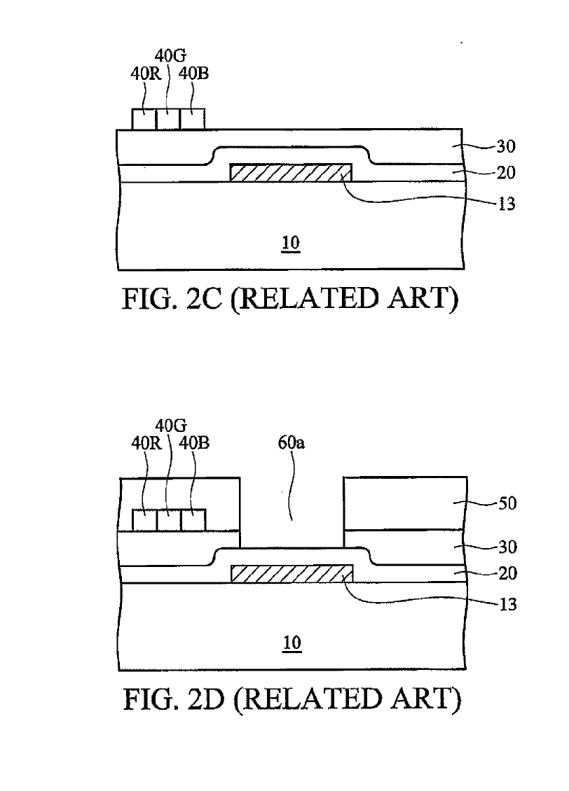

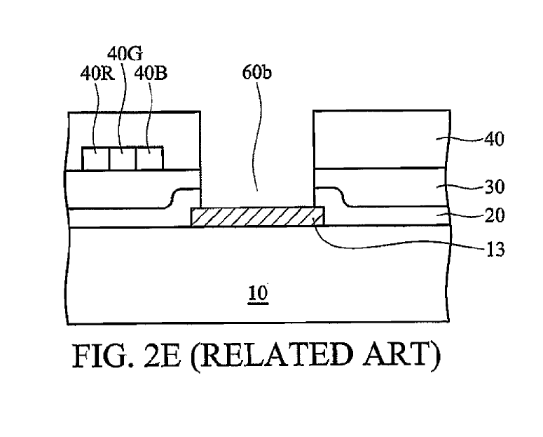

### DETAILED DESCRIPTION OF THE PREFERRED EMBODIMENTS

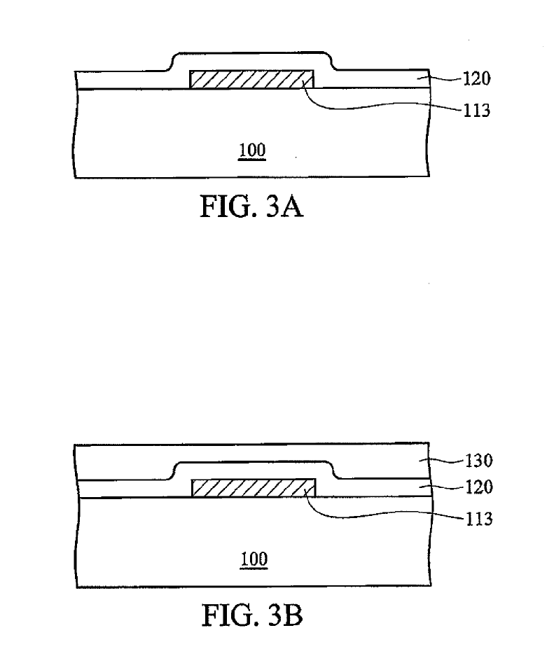

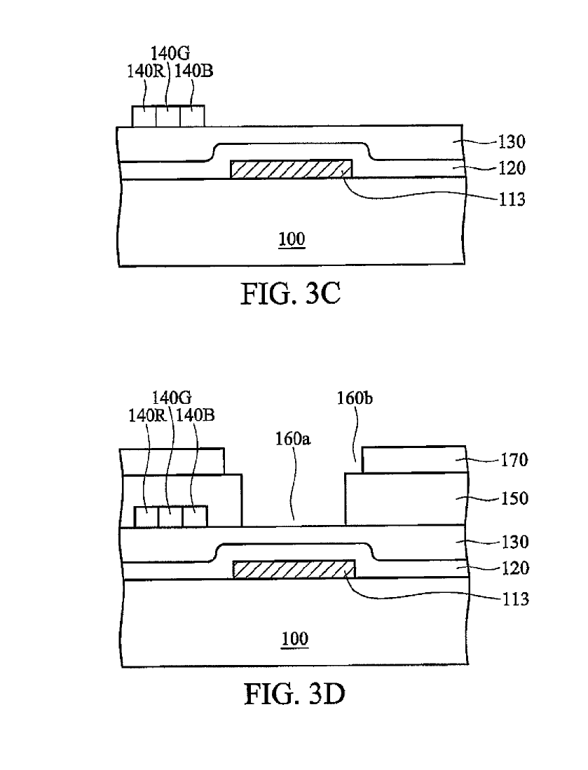

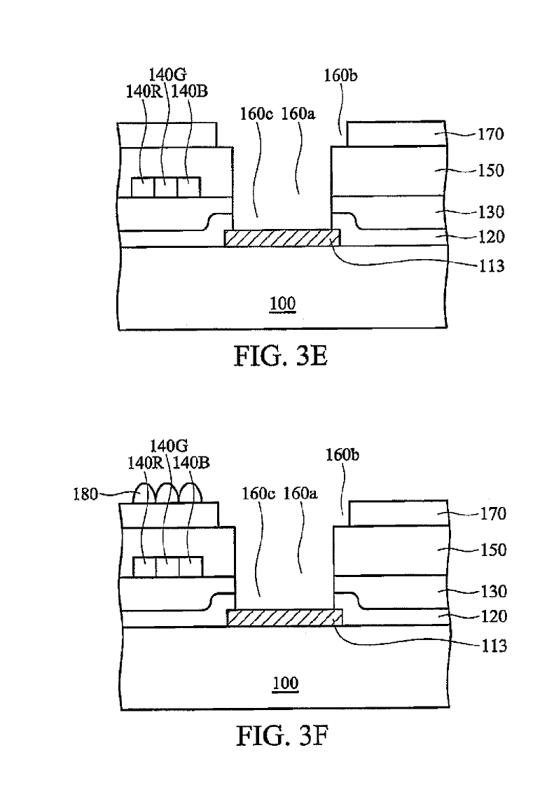

In FIG. 3A, a substrate 100, for example a semiconductor substrate, with a sensor pixel array (not shown) and a contact pad 113 formed thereon is provided. The sensor pixel array can be an array of image sensors such as complementary metal-oxide-semiconductor (CMOS) image sensors. The contact pad 113 may comprise alloy of aluminum-copper-aluminum (Al—Cu—Si) or Al—Cu formed by physical vapor deposition (PVD) at a thickness of about 5000-10000 Å. A passivation layer 120 is formed on the substrate 100 to cover the sensor pixel array and the contact pad 113. The passivation layer may comprise silicon oxide or silicon nitride formed by chemical vapor deposition (CVD) or plasma enhanced chemical vapor deposition (CVD) at a thickness of about 6000-8000 Å.

In FIG. 3B, a first planarization layer 130 is formed on the passivation layer 120. The first planarization layer 130 may comprise photoresists with light transmittance not less than 95%, such as photosensitive polyimide or other negative-type photoresists. The first planarization layer 130 has high tolerance to exposure and corrosion from developers used and has a plane surface after planarization is performed thereon.

In FIG. 3C, color filter layers 140B, 140R, 140G of blue, red and green color are sequentially formed on the first planarization layer 130 corresponding to the sensor pixel array. For example, first forming a blue color layer 140B on the first planarization layer 130 and then sequentially exposing and developing, thus forming patterned blue color filter elements 140B on the sensor pixel array. Next, a red color layer 140R is formed on the first planarization layer 130 and sequential exposure and development steps are then performed thereon, forming patterned red color filter elements 140R on the sensor pixel array. Next, a green color layer 140G is formed on the first planarization 130 and sequential exposure and development steps are then performed thereon, forming patterned green color filter elements 140G on the sensor pixel array. The color filter layers 140B, 140R, 140G may comprise photoresists of high resolution with resolution, for example, less than 2.0 μm.

In FIG. 3D, a second planarization layer 150 is formed on the first planarization layer 130 to cover the color filter layers 140R, 140G, 140B. The second planarization layer 150 may comprise photoresists with light transmittance not less than 95%, such as photosensitive polyimide or other negative-type photoresists. The second planarization layer 150 may comprise the same material as that of the first planarization layer 130. Next, sequential exposure and development on the second planarization layer 150 form a first opening 160a therein, exposing the top surface of the first planarization layer 130 in the first opening 160a.

Next, a third planarization layer 170 is formed on the second planarization 150 and fills the first opening 160a. The third planarization may comprise photoresist with light transmittance not less than 95%, such as photosensitive polyimide or other negative-type photoresists. The third planarization layer 170 may comprise the same material as that of the first and second planarization layers 130, 150. Next, sequentially exposing and developing are performed, thus forming a second opening 160b therein, exposing the top surface of the first planarization layer 130 in the second opening 160b.

In FIG. 3E, dry etching on the first planarization layer 130 and the passivation layer 120 forms a third opening 160c, using the second and third planarization layers 150, 170 as etching masks, and exposes the top surface of the contact pad 113 in the third opening 160c. The etching can use reactive ion etching using CF₄, CHF₃ or other reactive gases as etchants for etching the first planarization layer 130 and the passivation layer 120. A contact opening is formed after formation of the color filter layers and thus corrosion of the top surface of the contact pad therein is prevented and various undesired coated photoresist layers can be thus overcome.

In FIG. 3F, microlens elements 180 are then formed on the third planarization layer 170 corresponding to the sensor pixel array and the color filter layers.

As illustrated in rig. 3F, a color image sensor device is also provided, comprising a substrate with a sensor pixel array in a central region and a contact pad in a peripheral region. A passivation layer 120 on the substrate 100 covers the sensor pixel array and the contact pad. A first planarization layer 130 is on the passivation layer 120. Color filter layers 140R, 140G, 140B on the first planarization layer 130 correspond to the sensor pixel region. A second planarization layer 150 on the first planarization layer 130 covers the color filter layers 140R, 140G, 140B. An opening (i.e. the first opening 160a) in the second planarization layer 150 corresponds to the contact pad 113 as does the third opening 160c in the first planarization layer 130 and the passivation layer 120. The color image sensor device further comprises a third planarization layer 130 formed on the second planarization layer 150, having yet another opening (referring to the second opening 160b) corresponding to the contact pad 113, and microlens elements 180 disposed on the third planarization layer 170 correspond to the sensor pixel array.

One of the potential advantages of the described embodiment is a contact opening down to the contact pad is formed after formation of the color filter layers and corrosion thereto by a developer solution used for developing the color filter layers can be thus prevented. In addition, the contact opening is formed in the first planarization layer 130 and the passivation layer 120 by a dry etching and exposes top surface of the contact pad 113. The first planarization layer 130 is exposed and developed for several times during formation of the color filter layers and the contact opening can be formed only by dry etching but cannot formed by developer development.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a color image sensor device, comprising:
providing a substrate having a sensor pixel array and a contact pad;
forming a passivation layer on the substrate, covering the sensor pixel array and the contact pad;
forming a first planarization layer on the passivation layer;
forming a plurality of color filter elements on the first planarization layer corresponding to the sensor pixel array;
a forming a second planarization layer on the first planarization layer, covering the color filter elements;
forming a first opening in the second planarization layer, exposing the first planarization layer, corresponding to the contact pad; and
dry etching the first planarization layer along the first opening, forming a second opening in the first planarization layer and the passivation layer and exposing the contact pad.

2. The method as claimed in claim 1, wherein the passivation layer has silicon oxide and silicon nitride.

3. The method as claimed in claim 1, wherein the first planarization layer is a photoresist with light transmittance not less than 95%.

4. The method as claimed in claim 1, wherein formation of the color filter elements further comprises:
forming a first color layer on the first planarization layer;
exposing and developing to form a patterned first color filter element over the sensor pixel array;
forming a second color layer on the first planarization layer;
exposing and developing to form a patterned second color filter element over the sensor pixel array;
forming a third color layer on the first planarization layer; and
exposing and developing to form a patterned third color filter element over the sensor pixel array.

5. The method as claimed in claim 1, wherein the second planarization layer is a photoresist.

6. The method as claimed in claim 1, wherein the first opening is formed in a development step.

7. The method as claimed in claim 1, further comprising forming a microlens array over the second planarization corresponding to the sensor pixel array.

8. A method for forming a color image sensor device, comprising:
providing a substrate having a sensor pixel array and a contact pad;
forming a passivation layer on the substrate, covering the image sensor pixel array and the contact pad;
forming a first planarization layer on the passivation layer;
forming a plurality of color filter elements on the first planarization layer corresponding to the sensor pixel layer;
forming a second planarization layer on the first planarization layer, covering the color filter elements;
forming a third planarization layer on the second planarization layer;
forming a first opening in the third planarization layer, exposing the second planarization layer therein, corresponding to the contact pad;
forming a second opening in the second planarization layer, exposing the first planarization layer, corresponding to the contact pad; and
dry etching the first planarization along the first opening, forming a third opening in the first planarization layer and the passivation layer, and exposing the contact pad.
